(19) United States
(12) Patent Application Publication
(10) Pub. No.: US 2010/0104953 A1
(43) Pub. Date: Apr. 29, 2010

(54) PROCESS AND HARDWARE FOR PLASMA TREATMENTS

(76) Inventors: James S. Papanu, San Rafael, CA (US); Roman Gouk, San Jose, CA (US); Han-Wen Chen, San Mateo, CA (US); Phillip Peters, Campbell, CA (US)

Correspondence Address: APPLIED MATERIALS/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/258,271

(22) Filed: Oct. 24, 2008

(51) Int. Cl. G03F 1/00

(52) U.S. Cl. 430/5; 239/556

(57) ABSTRACT

A H₂O vapor based dry plasma process for pre-treating and strip-cleaning a reticle, a three layer gas distribution plate (GDP) assembly to control the heat load to the reticle during the plasma process, and a modified hole pattern for the GDP that further enhances stripping of resist from the edges of the reticle are disclosed.

### BACKGROUND

1. Field

Embodiments of the present invention relate to the field of semiconductor processing and manufacturing. More particularly, embodiments of the invention relate to the area of cleaning and stripping resist from a substrate such as reticle.

2. Background Information

Lithography is a well established process in the manufacture of semiconductor devices in which a pattern from a reticle (also known as a mask) is transferred to a layer of resist deposited on the surface of a semiconductor substrate. The kind of lithography depends on the wavelength of radiation used to expose the resist. Photolithography (or optical lithography) uses UV radiation, X-ray lithography uses X-ray, e-beam lithography uses electron bean, ion beam lithography uses ion beam. The kind of reticle can also depend upon wavelength of radiation used as well as the complexity of the pattern being transferred. Common reticles include, for example, binary (chrome on glass), attenuated phase shift, and alternating phase shift.

The reticle may be created by a number of different techniques, depending on the method of writing the pattern on the reticle. Due to the dimensional requirements of current semiconductor structures, the writing method is generally with a laser or e-beam. Advanced reticle manufacturing materials frequently include combinations of layers of materials such as chromium (Cr), chromium oxide (CrOₓ), chromium oxynitride (CrOₓN_{y}), molybdenum (Mo), and molybdenum silicide (MoSi). As shown in FIG. 1A, a typical process for forming an attenuated phase shift reticle may include: providing a glass or quartz plate 110, depositing a phase shift layer 112 such as MoSi on the glass or quartz surface, depositing a chromium layer 114 on the phase shift layer 112, depositing an antireflective coating (ARC) layer 116 such as CrOₓ or CrOₓN_{y} over the Cr layer 114, and applying a resist layer 118 over the ARC layer 116.

As shown in FIG. 1B, resist layer 118 is exposed with a laser or e-beam and developed to form a predetermined pattern in the resist layer 118. Thereafter, as shown in FIG. 1C, selective etch chemistries are utilized to selectively etch the ARC layer 116, Cr layer 114, and the phase shift layer 112 while using the photoresist pattern 118 as an etching mask (though Cr layer 114 can also be used as hard mask for phase shift layer 112 etch). The remaining first resist layer 118 is then stripped in FIG. 1D.

Then a second resist layer 120 is formed on the patterned ARC layer 116 and quartz substrate 110, as shown in FIG. 1E. Resist layer 120 is exposed with a laser or e-beam and developed to form a second predetermined pattern as shown in FIG. 1F. Thereafter, the exposed portions of ARC layer 116 and Cr layer 114 are removed by using the second resist pattern 120 as the etching mask, as shown in FIG. 1G. Finally, the remaining resist 120 is stripped in FIG. 1H.

A resist used in lithography is generally spin coated on the surface of a reticle as a cast thin film, and residual solvent is then removed with a low temperature bake. As shown in FIG. 2A, a common artifact associated with spin coating a resist layer 218 onto a reticle 200 is that a resist bump 220 forms along the top 202 and vertical surfaces 204 near the edges of the reticle 200. For example, resist 218 of FIG. 2A could be the resist layers 118 or 120 described in relation to FIG. 1A-FIG. 1G.

The reticle is typically supported along the edges or corners with a minimal contact support adaptor during the low temperature bake. Heat may transfer through the minimal support contacts thereby transferring additional heat during low temperature baking. As a result, the resist bump 220 on the top 202 and vertical surfaces 204 near the edges and/or corners of the reticle 200 can be more difficult to remove not only because of the increased thickness, but also because a higher percentage of hardened organics is present as a result of having received more heat during the low temperature bake.

A conventional method for reducing the resist bump 220 near the edges of the reticle 200 is to perform an edge bead removal (EBR) process in which solvent is applied directly to the edge of the reticle (or back side so that it wicks around the edges) and removes several mm of the resist bump 220 near the edges of the reticle 200. However, the EBR process requires additional processing, and may not completely remove the resist bump 220 so that the resist bump 220 is merely rendered less pronounced. Therefore, as shown in FIG. 2B, whether an EBR process is performed or not, an amount of over strip is typically required to completely remove remnants of the resist bump 220 near the edges of the reticle 200 after the bulk of the resist has been removed from the top surface 202 of the reticle.

Referring now to FIG. 2C, another common problem associated with lithography is that organic and non-organic surface particles 214 are inevitably deposited on the top surface 202 of the reticle 200 during fabrication and ordinary handling. As a result, the reticle must be routinely cleaned during its lifetime to remove surface particles 214. In particular, non-spherical particles having a large surface contact area with the reticle, and resist or other organic particles on reticles that have been stored for long periods of time can be difficult to remove, requiring extended stripping time and exposure to chemicals.

Conventional processes for stripping and cleaning both resist layers and surface particles from a reticle include both dry processes and wet processes. Dry stripping is typically performed in a chamber with oxygen (O₂) based plasmas at a temperature above 150° C. However, it has been reported that plasma stripping of both positive and negative resists with an oxygen based plasma can result in degradation of the anti-reflective (ARC) layer 116, as well as undercutting of the phase shift layer 112. One proposal has been to add up to 10% hydrogen (H₂) to the O₂ plasma to suppress the attack of the ARC layer. While the H₂ chemistry is found to be more ARC layer “friendly,” it is not effective in removing the resist bump 220 from the top 202 and vertical surfaces 204 near the edge of the reticle 200 where the resist is thicker. Consequently 100-200% overstrip may be required at the expense of damaging the ARC layer and reducing the lifetime that the reticle.

Wet strip and clean processes can typically be performed using a process of applying a stripping solution and a subsequent cleaning solution to the reticle. In applications in which a wet strip is used, a sulfuric acid and hydrogen peroxide mixture (SPM) at 120° C. or ozone dissolved in deionized water (O₃/DI water) in a range from about 15 ppm to about 80 ppm is typically used. SPM is a relatively fast stripper, but leaves sulfur residue on the reticle which causes photon induced haze formation during subsequent exposure. O₃/DI water stripping does not cause haze formation but requires extended contact time often approaching 60 minutes, particularly for removing resist or other organic particles (214 of FIG. 2C) with a high surface area and thicker resist bumps (220 of FIG. 2A-FIG. 2B) near the edges of a reticle. In either case, charge accumulation and electrostatic discharge (ESD) is an inherent problem with all wet processes which may potentially cause local pattern damage and critical dimension (CD) shifts due to electrochemical reactions.

After wet stripping, the reticle is typically wet cleaned. However, extended exposure to cleaning solutions including ammonium hydroxide (NH₄OH) and hydrogen peroxide (H₂O₂), also known as an APM mixture, is known to attack the ARC layer and change the reflectivity. As a result, a reticle may only be cleaned a certain number of times during its lifetime before the reflectivity of the ARC layer is outside acceptable limits.

Accordingly, a process and hardware is needed for stripping and/or cleaning a reticle which is more compatible with the combinations of layers of materials, and can reduce the required amount of exposure to chemicals.

### SUMMARY

Embodiments of the present invention disclose a H₂O vapor based dry plasma that can be utilized in pre-treating and strip-cleaning processes. A reticle having resist disposed on a top surface is placed onto a reticle holder and in spaced apart relation with a processing pedestal. A plasma pretreatment including H₂O vapor and optionally a gas are applied to the reticle. In an embodiment, a plasma processing chamber comprises a three layer gas distribution plate.

### BRIEF DESCRIPTION OF THE DRAWINGS

FIG. 1A-FIG. 1H are side view illustrations of a conventional process for forming a phase shift reticle.

FIG. 2A is a side view illustration of a resist layer including a resist bump formed along the top and vertical surfaces near the edges of a reticle.

FIG. 2B is a side view illustration of remnants of a resist bump near the edges of a reticle after the bulk of a resist layer has been removed from the top surface of the reticle.

FIG. 2C is a side view illustration of surface particles on the top surface of a reticle.

FIG. 3A is an illustration of a conventional cleaning process incorporating an O₃/DI water pre-treatment operation.

FIG. 3B is an illustration of a cleaning process incorporating a H₂O vapor based dry plasma pre-treatment operation.

FIG. 4A is a particle map of a reticle cleaned utilizing the process of FIG. 3A.

FIG. 4B is a particle map of a reticle cleaned utilizing the process of FIG. 3B.

FIG. 5A is an illustration of a conventional all-wet cleaning process incorporating an O₃/DI water pre-conditioning/stripping operation.

FIG. 5B is an illustration of a dry-wet cleaning process incorporating a H₂O vapor based dry plasma pre-conditioning/stripping operation.

FIG. 6A is a particle map of a reticle cleaned utilizing the all-wet cleaning process of FIG. 5A.

FIG. 6B is a particle map of a reticle cleaned utilizing the dry-wet cleaning process of FIG. 5B.

FIG. 7 is an illustration of a dry-wet strip and clean process incorporating a H₂O vapor based dry plasma strip followed by wet cleaning.

FIG. 8 is an illustration comparing the reflectivity data for sequential cleaning processes performed after a conventional SPM stripping process, and after a H₂O vapor based dry plasma stripping process.

FIG. 9 is an illustration of a wet-dry-wet strip and clean process in which either or both O₃/DI water and a H₂O based dry plasma treatment are responsible for stripping resist from a reticle.

FIG. 10 is an illustration of a dry-wet-dry-wet strip and clean process in which a first H₂O based dry plasma treatment is added to the process of FIG. 9.

FIG. 11 is a top-down schematic illustration of a system which combines wet chambers and a dry plasma chamber in a single platform.

FIG. 12A is side view illustration of the dry plasma chamber.

FIG. 12B is a top view illustration of a GDP perforation pattern including multiple perforations arranged in a rectangular outline pattern.

FIG. 12C-FIG. 12E is a side view illustrations of a three layer gas distribution plate (GDP) assembly.

### DETAILED DESCRIPTION

Embodiments of the present invention disclose a process and hardware for cleaning and/or stripping a substrate such as a reticle.

Various embodiments described herein are described with reference to figures. However, certain embodiments may be practiced without one or more of these specific details, or in combination with other known methods and configurations. In the following description, numerous specific details are set forth, such as specific configurations, compositions, and processes, etc., in order to provide a thorough understanding of the present invention. In other instances, well-known semiconductor processes and manufacturing techniques have not been described in particular detail in order to not unnecessarily obscure the present invention. Reference throughout this specification to “one embodiment” or “an embodiment” means that a particular feature, configuration, composition, or characteristic described in connection with the embodiment is included in at least one embodiment of the invention. Thus, the appearances of the phrase “in one embodiment” or “an embodiment” in various places throughout this specification are not necessarily referring to the same embodiment of the invention. Furthermore, the particular features, configurations, compositions, or characteristics may be combined in any suitable manner in one or more embodiments.

Embodiments of the invention provide a method for cleaning and/or stripping particles and resist layers from a reticle with a H₂O vapor based dry plasma treatment. An inert gas such as He, Ar, and/or H₂, and combinations thereof, may be included in the H₂O vapor based dry plasma treatment with the H₂O concentration varying from 10%-100% standard volumetric (i.e. molar) ratio. Additionally, a small amount of O₂ gas up to 30% standard volumetric ratio can be included. The H₂O vapor based dry plasma treatment is characterized as both partially reducing and partially oxidizing. Oxidation occurs but is mitigated by reduction, which avoids the detrimental side effects of conventional O₂ based dry plasma cleans. The H₂O vapor based dry plasma treatment in accordance with embodiments of the present invention is highly selective to reticle films including Cr and MoSi with minimal change to the optical properties of these films. Additionally, the inherent isotropic nature of the H₂O vapor based remote dry plasma treatment provides a high efficacy for removing resist from reticle edges. As a result, the amount of exposure to wet chemicals and/or overstrip required to remove edge resist and particles with a large surface contact area is reduced.

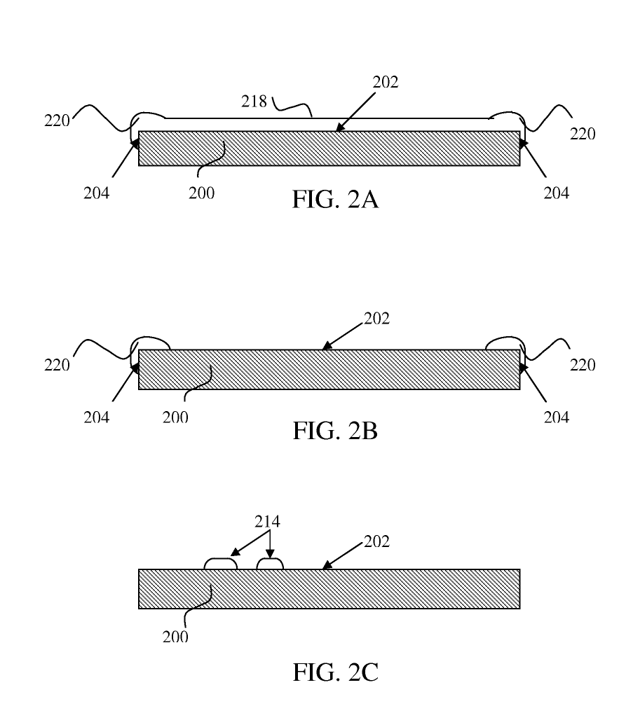

The H₂O vapor based dry plasma treatment can be incorporated into cleaning and/or stripping processes in a variety of manners. In one embodiment, the H₂O vapor based dry plasma treatment can be included in a dry-wet cleaning process. The dry-wet cleaning process is more robust that an all-wet cleaning process for several reasons. The H₂O vapor based dry plasma treatment is effective in converting the surface of a hydrophobic state to a hydrophilic state. This can be particularly useful for pre-treating a reticle which has an established organic surface layer due to the adsorption of organics from the environment or reticle container outgassing. The H₂O vapor based dry plasma treatment also assists in cleaning of difficult to remove particles, such as non-spherical particles (such as particles 214 in FIG. 2C) and hard organic particles that may be present on a reticle which has been stored for an extended period of time, for example, for later lithography rework or after post-etch stripping. In one embodiment, the H₂O vapor based dry plasma treatment may be included in a dry-wet stripping process in which resist is stripped from all reticle surfaces exposed to a H₂O vapor based dry plasma treatment. In one embodiment, the H₂O vapor based dry plasma treatment may be included in a wet-dry-wet stripping and cleaning process in which either or both O₃/DI water and the H₂O based dry plasma treatment are responsible for stripping resist from a reticle. In another embodiment, the H₂O vapor based dry plasma treatment may by included in a dry-wet-dry-wet process in which the first H₂O vapor based dry plasma treatment pre-treats the surface of a reticle and the second H₂O based dry plasma treatment strips resist from the reticle. The duration and conditions of the H₂O vapor based dry plasma treatment determine whether the process is considered to be pre-treatment surface conditioning, particle cleaning, partial stripping, or complete resist stripping.

In an embodiment, an inert gas such as He, Ar, and/or H₂, and combinations thereof, may be included in the H₂O vapor based dry plasma treatment with the H₂O concentration varying from 10-100% standard volumetric ratio depending on the gas composition chosen. In an embodiment, the H₂O concentration is between 20%-40% standard volumetric ratio for a pre-treatment application. In an embodiment, the H₂O concentration is 40%-100% standard volumetric ratio for a stripping application, with higher H₂O concentrations where more stripping is desired. The addition of O₂ also increases stripping rate of the H₂O vapor based dry plasma. In an embodiment, up to 10% standard volumetric ratio O₂ can be added for a pre-treatment operation. In an embodiment, 10%-30% standard volumetric ratio O₂ can added to the H₂O vapor based dry plasma to increase etch rate during a stripping operation without causing damage to the reticle films. In an embodiment, the H₂O based plasma chemistry allows edge-fast resist stripping which requires only 50-100% overstrip to completely remove a resist bump near the top and vertical surfaces at the edge of the reticle. This is a significant improvement compared to O₂ based plasma stripping which requires 100-200% overstrip. Additionally, the H₂O based plasma chemistry has a high selectivity to the ARC layer, with no damage after exposures extended for at least 10 minutes.

In another embodiment, the heat load to the reticle during a H₂O vapor based dry plasma treatment in a dry plasma chamber is reduced using a three layer gas distribution plate (GDP) assembly. In an embodiment, the three layer GDP assembly includes an intermediate plate sandwiched between a top and bottom plate. The intermediate plate is opaque to infra-red (IR) radiation, thereby reducing the amount of IR radiation absorbed by the reticle which helps reduce warpage that is often associated with conventional plasma treatment processes. In an embodiment, the three layer GDP assembly has a square perforation pattern that is designed to direct the gas flow to the edges of the reticle. This intentional non-uniformity allows the neutral reactive gas species to be focused on the edges of the reticle while reducing the effective amount of overstrip or chemical contact on the rest of the reticle, which helps maintain the optical integrity of the reticle films.

In an embodiment, exemplary gas chemistries and processing conditions for pre-treatment surface conditioning and stripping in a dry plasma chamber are provided in Table 1. While specific chemistries and processing conditions are disclosed in Table 1, it is understood that the specific gas chemistries, process conditions and applications provided are only exemplary, and are not meant to be limiting.

TABLE 1
Exemplary plasma process conditions

| | | Pedestal | | | |
|---|---|---|---|---|---|
| | Gas Flow Rate | Temperature | RF Power | Chamber | |
| Chemistry | (slm) | (deg C.) | (kW) | Pressure (Torr) | Application |
| H₂O | 2.5-3 | 80-120 | 2-5 | 0.5-3.0 | Stripping |
| H₂O/O₂ | 3/0.3-3/0.9 | 80-120 | 2-5 | 0.5-3.0 | Conditioning/ |
| | | | | | Stripping |
| H₂O/(He or Ar) | 0.5/3-3/3 | 80-120 | 2-5 | 0.5-3.0 | Conditioning/ |
| | | | | | Stripping |
| H₂O/H₂ | 0.3/3-3/3 | 80-120 | 2-5 | 0.5-3.0 | Stripping |
| H₂O/H₂/He | 0.3/3/3-3/3/3 | 80-120 | 2-5 | 0.5-3.0 | Stripping |

### EXAMPLE 1

### Dry-Wet Cleaning Process

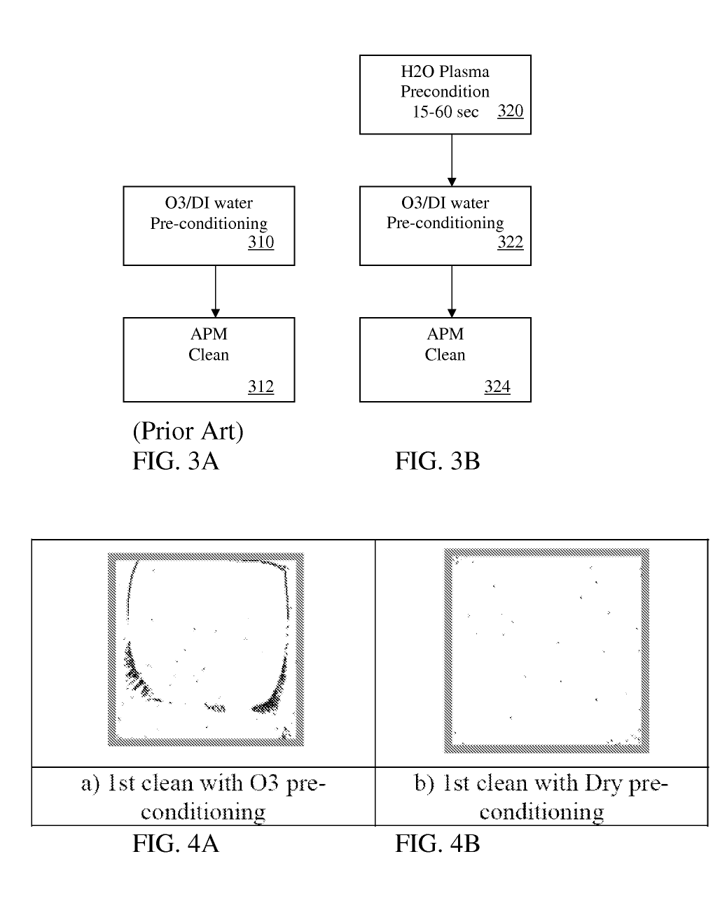

In one embodiment, a H₂O vapor based dry plasma treatment is included in a surface pre-treatment process for wet cleaning. FIG. 3A and FIG. 3B compare a conventional reticle cleaning process to a cleaning process incorporating a H₂O vapor based dry plasma pre-treatment in accordance with embodiments of the present invention.

As shown in FIG. 3A, a conventional reticle pre-treatment and cleaning technique includes an O₃/DI water precondition including approximately 15 ppm to about 80 ppm dissolved O₃. A solution of O₃/DI water is applied at 1.5-3 L/min to the surface of a reticle spinning at 100-200 rpm for 5-10 minutes at operation 310 in order to covert a hydrophobic surface condition (due to residual or adsorbed organics) on the reticle to a hydrophilic condition. Without this conversion, the reticle surface cannot be consistently wetted with a water based cleaning solution. Subsequently APM mixture is applied at 0.5-1.0 L/min to the surface of the reticle spinning at 5-30 rpm for 60-120 seconds at operation 312. Examples of APMs include Standard Clean-1 (SC-1) and AM-Clean™ (available from Applied Materials, Inc., Santa Clara, Calif.) which is a solution resulting from the mixture of ammonium hydroxide (NH₄OH), hydrogen peroxide (H₂O₂), water (H₂O), a chelating agent, and a surfactant. The mixture of ammonium hydroxide, surfactant and chelating agent is sold in a proprietary blend known as AMI (available from Mitsubishi Chemical Corporation, Tokyo, Japan).

However, the conventional pre-treatment operation 310 is not always effective in converting the surface of the reticle from a hydrophobic condition to a hydrophilic condition. For example, new reticles or reticles that have been stored for an extended period of time, such as when the reticle is stored for later lithography rework or stored after post-etch stripping, may have a more established organic surface layer due to organics adsorbing onto the reticle surface from the environment or reticle container out gassing. As a result, hydrophobic to hydrophilic conversion is not always robust with an O₃/DI water pre-treatment, and water marks are sometimes observed. Results of the cleaning method of FIG. 3A are provided in the particle map of FIG. 4A.

FIG. 3B is an illustration of an embodiment in which a H₂O vapor based dry plasma pre-treatment is incorporated into a pre-treatment process for wet cleaning. As shown, a H₂O vapor based dry plasma pre-treatment is applied to the reticle for approximately 15-60 seconds at operation 320. An inert gas such as He, Ar, H₂, and/or He may be included in the H₂O vapor based dry plasma treatment. For example, the exemplary chemistries and processing conditions of Table 1 can be used. In an embodiment, the H₂O concentration is between 20%-40% standard volumetric ratio. In an embodiment, less than 10% standard volumetric ratio O₂ gas can be added to the H₂O vapor based dry plasma. The H₂O vapor based dry plasma pre-treatment operation 320 is subsequently followed by an O₃/DI water precondition operation 322 and APM clean operation 324 as described in relation to FIG. 3A. Results of the cleaning method of FIG. 3B are provided in the particle map of FIG. 4B. A comparison of the particle maps of FIG. 4A and FIG. 4B suggests that for highly hydrophobic surfaces a short dry plasma pre-treatment of 15-60 seconds provides a much more robust hydrophobic to hydrophilic conversion. As a result, the dry pre-treatment operation 320 prior to wet cleaning enables higher particle removal efficiency (PRE) and no water mark type additive defects relative to a wet-only process.

In one embodiment, the H₂O vapor based dry plasma pre-treatment operation 320 is performed for new reticles or reticles which have been stored for long periods of time, where an organic layer is more established.

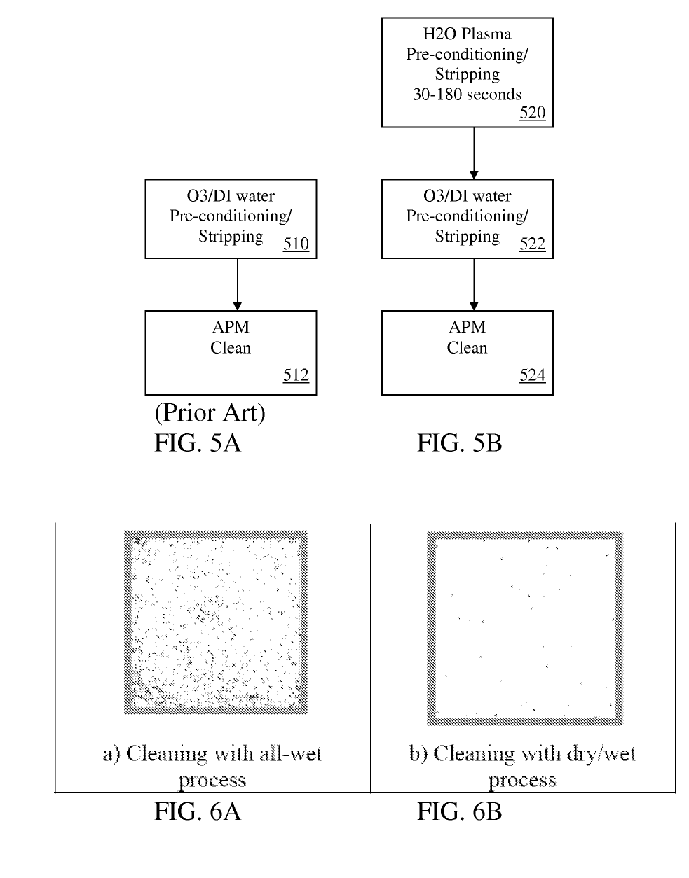

In one embodiment, the H₂O vapor based dry plasma treatment may be included in a dry-wet process for cleaning of difficult to remove particles. For example, non-spherical particles with a flat shape and large surface contact area (several to tens of percent) on a reticle (such as particles 214 in FIG. 2C) have a large adhesion force to the reticle and are difficult to remove. This is particularly true for certain types of organic particles. Additionally, hard organic or resist particles that may be present on a reticle that has been stored for an extended period of time, such as for later lithography rework or post-etch striping, can be difficult to remove. FIG. 5A and FIG. 5B compare a conventional reticle cleaning process to a cleaning process incorporating a H₂O vapor based dry plasma pre-conditioning/stripping operation in accordance with embodiments of the present invention. The processes corresponding to FIG. 5A and FIG. 5B are identical to the processes of FIG. 3A and FIG. 3B except for the durations required for each operation. As shown in FIG. 5A, a conventional particle removal process includes O₃/DI water conditioning at 1.5-3 L/min for 5-10 minutes while spinning the reticle at 100-200 rpm at operation 510, followed by an APM exposure at 0.5-1.0 L/min for 60-120 seconds while spinning the reticle at 5-30 rpm at operation 512. In an embodiment shown in FIG. 5B, a reticle can be first exposed to a H₂O based dry plasma treatment for 30-180 seconds at operation 520. In an embodiment, the H₂O concentration is 20%-100% standard volumetric ratio, with the amount of H₂O concentration depending on the amount of stripping desired. Likewise up to 30% standard volumetric ratio O2 may be added, with the amount depending on the amount of stripping desired. The H₂O based dry plasma treatment strips the difficult to remove particles (such as particles 214 in FIG. 2C), and additionally assists in the hydrophobic to hydrophilic conversion of the reticle. The reticle is then optionally exposed to an O₃/DI water precondition at 1.5-3 L/min for 5-10 minutes while spinning the reticle at 100-200 rpm at operation 522, followed by an APM clean at 0.5-1.0 L/min for 60-120 seconds while spinning the reticle at 5-30 rpm at operation 524.

FIG. 6A and FIG. 6B show particle map results of the processes described above with regard to FIG. 5A and FIG. 5B, respectively, in which operations 510 and 522 were performed at 1.5-3 L/min for 5-10 minutes while spinning the reticle at 100-200 rpm, and 512 and 524 were performed with an exposure at 0.5-1.0 L/min for 60-120 seconds while spinning the reticle at 5-30 rpm, and the only difference is the inclusion of the H₂O based dry plasma treatment operation 520. As shown, the inclusion of the H₂O based dry plasma treatment operation 520 significantly increases the PRE.

### EXAMPLE 2

### Dry-Wet Stripping and Cleaning Process

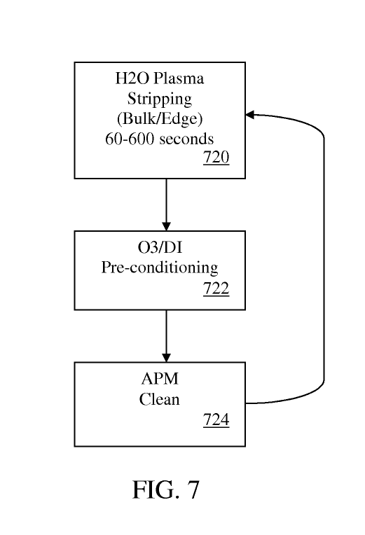

FIG. 7 is an illustration of an embodiment in which the H₂O vapor based dry plasma treatment is included in an all-dry process for stripping resist from all reticle surfaces exposed to the H₂O vapor based dry plasma treatment, followed by wet cleaning. A reticle can be first exposed to a H₂O based dry plasma treatment for 60-600 seconds at operation 720. In an embodiment, the H₂O concentration is 40%-100% standard volumetric ratio. In an embodiment, 10-30% standard volumetric ratio O₂ gas can be added to the H₂O vapor based dry plasma to increase etch rate without causing damage to the reticle films. The H₂O based dry plasma treatment strips the resist from the bulk of the resist layer 218 and resist bump 220 from the top surface 202 and vertical surfaces 204 near the edge of reticle 200 (as shown in FIG. 2A), and additionally assists in the hydrophobic to hydrophilic conversion of the reticle. The reticle is then exposed to an optional O₃/DI water treatment (to ensure that all resist residues are removed and that the hydrophobic to hydrophilic conversion is complete) at 1.5-3 L/min for 5-10 minutes while spinning the reticle at 100-200 rpm at operation 522, followed by an APM clean at 0.5-1.0 L/min for 60-120 seconds while spinning the reticle at 5-30 rpm at operation 524. In an embodiment, multiple dry-wet sequencing of FIG. 7 can be repeated to remove problematic residues.

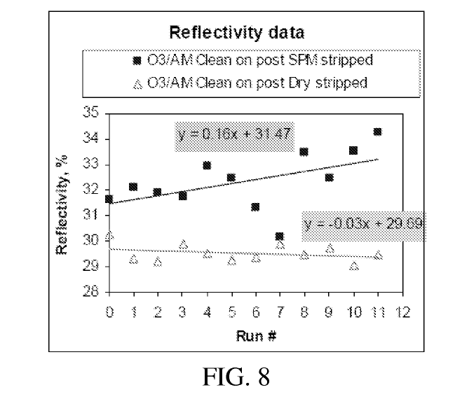

Embodiments of the present invention utilizing the H₂O based dry plasma treatment for resist stripping as described with regard to FIG. 7 have also been found to provide the additional benefit of increased resistance to Cr attack of the ARC layer and reduced reflectivity change during repeated subsequent cleaning processes. FIG. 8 is an illustration of the reflectivity change of an ARC layer subjected to repeated cleaning processes as previously described with regard to FIG. 5A after stripping a layer of resist utilizing either (1) a conventional SPM stripping solution, or (2) the H₂O based dry plasma treatment stripping operation 720 of FIG. 7. As shown in FIG. 8, repeated cleaning of a reticle initially stripped utilizing a conventional SPM stripping solution shows an approximately +1.76% change in reflectivity after 11 additional cleaning processes, whereas repeated cleaning of a reticle initially stripped utilizing the H₂O based dry plasma treatment stripping operation 720 of FIG. 7 shows virtually no change in reflectivity after 11 additional cleaning processes. As shown, the reflectivity change per clean is significantly lower when a dry-wet process of FIG. 7 is used for the initial stripping and cleaning of a reticle.

### EXAMPLE 3

### Wet-Dry-Wet Stripping and Cleaning Process

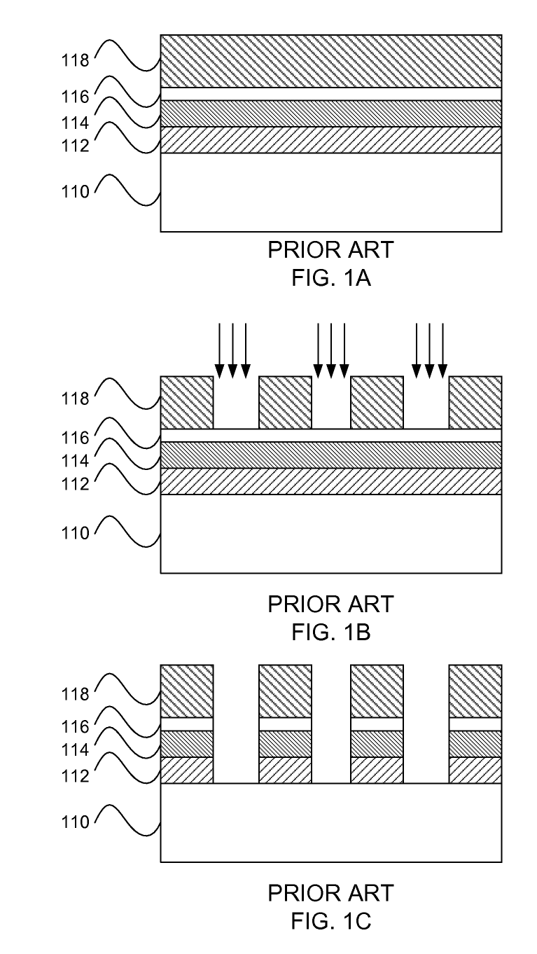

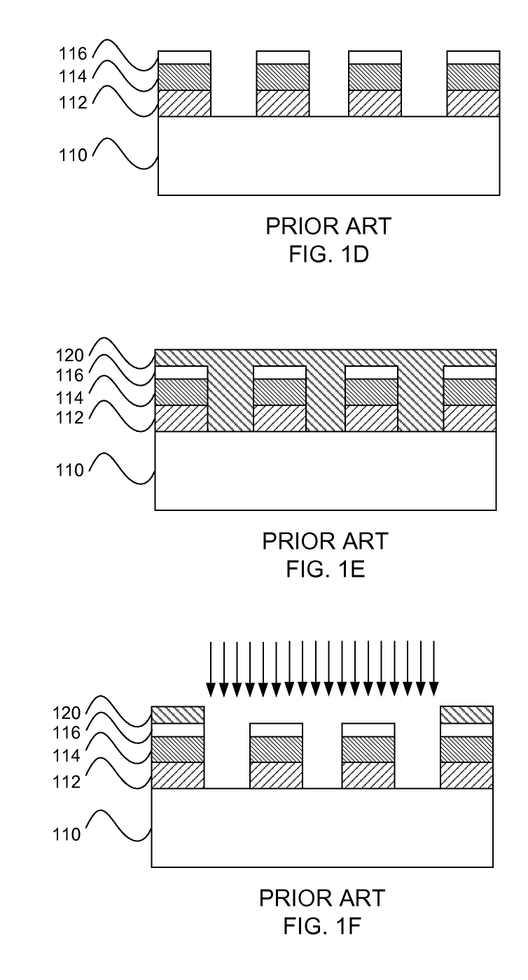

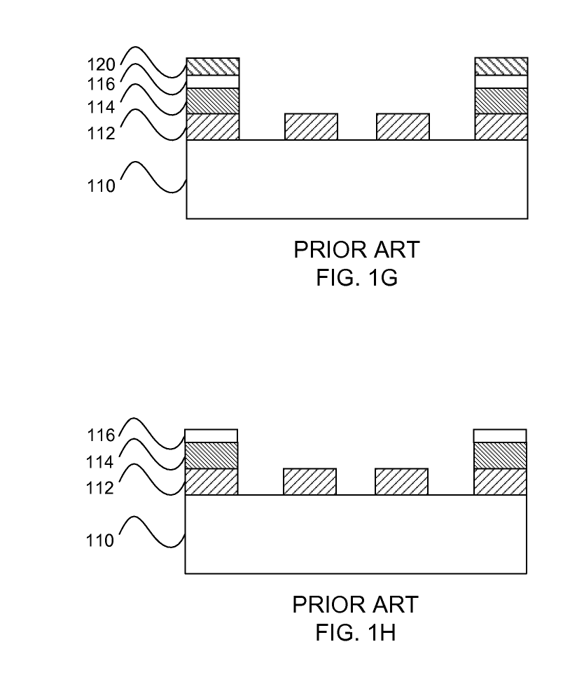

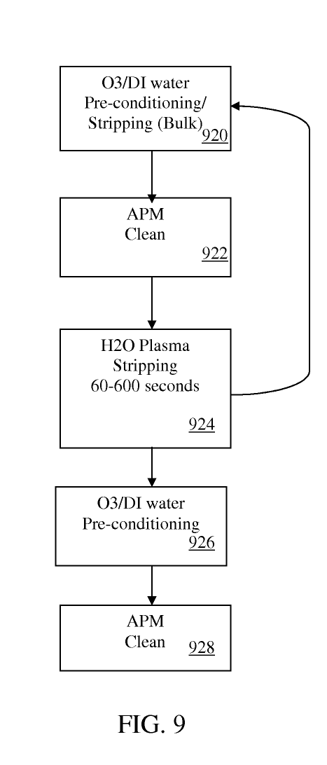

FIG. 9 is an illustration of an embodiment of a wet-dry-wet stripping and cleaning process in which a H₂O vapor based dry plasma treatment may only partially strip resist or organic residues from the reticle surfaces exposed to the H₂O vapor based dry plasma treatment, and is combined with a wet stripping and/or cleaning process for complete removal of the resist. In an embodiment, the cleaning process of FIG. 9 is used to remove problematic post-etch residues and particles. For example, it has been discovered that when plasma etching is used to etch the ARC layer 116, Cr layer 114, and/or MoSi layer 112 in FIG. 1B and FIG. 1F that organic residues form on the sidewalls of the patterned reticle. These organic residues can be further hardened even more if they are followed by an additional dry plasma operation. Accordingly, in one embodiment the wet-dry-wet stripping and cleaning process of FIG. 9 is used to remove post-etch organic residues.

A reticle can be first exposed to an O₃/DI water treatment at operation 920 for hydrophobic to hydrophilic conversion of the reticle, and to partially remove the resist or post-etch organic residues. The amount of time the reticle is exposed to the O₃/DI water treatment can vary according to application. Subsequently an APM clean operation 922 is performed on the reticle to remove residuals from operation 920. The reticle can then be exposed to a H₂O based dry plasma treatment for 60-600 seconds at operation 924. The H₂O based dry plasma treatment strips the resist (including edge resist if present) or post-etch organic residues completely. In an embodiment, the H₂O concentration is 40%-100% standard volumetric ratio. In an embodiment, 10-30% standard volumetric ratio O₂ gas can be added to the H₂O vapor based dry plasma to increase etch rate without causing damage to the reticle films. The reticle is then exposed to an O₃/DI resist residual removal operation 926, followed by an APM clean operation 928. Alternatively, depending upon the application and difficulty of removing the resist or post-etch organic residues, operation 920 may be repeated after operation 924 if the resist or post-etch organic residue is not completely stripped, and the cycle repeated. Utilizing the embodiment of FIG. 9, a stripping and cleaning operation can be specifically tailored in which either or both O₃/DI water and the H₂O based dry plasma treatment are responsible for stripping the resist or post-etch organic residues from the reticle.

### EXAMPLE 4

### Dry-Wet-Dry-Wet Preconditioning, Stripping and Cleaning Process

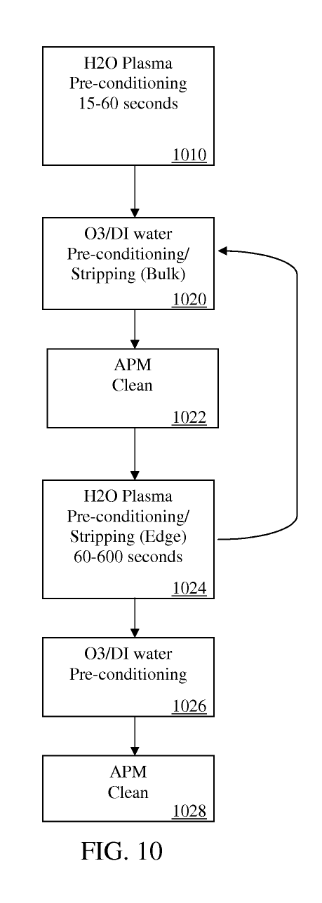

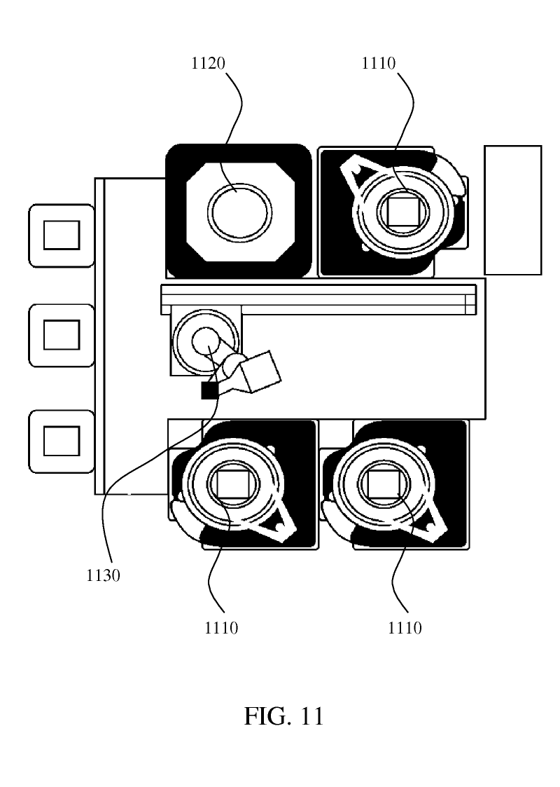

FIG. 10 is an illustration of an embodiment of a dry-wet-dry-wet stripping and cleaning process in which a first H₂O vapor based dry plasma treatment is added at the beginning of the wet-dry-wet stripping and cleaning process described in FIG. 9 to enhance wetting at the onset of the O₃/DI application. A H₂O vapor based dry plasma pre-treatment is applied to the reticle for approximately 15-60 seconds at operation 1010. An inert gas such as He, Ar, H₂, and/or He may be included in the H₂O vapor based dry plasma treatment. For example, the exemplary chemistries and processing conditions of Table 1 can be used. In an embodiment, the H₂O concentration is between 20%-40% standard volumetric ratio. In an embodiment, less than 10% standard volumetric ratio O₂ gas can be added to the H₂O vapor based dry plasma. The remainder of operations 1020 through 1028 are identical to operations 920 through 928 described above in FIG. 9.

### Hardware

Embodiments of the present invention may be performed in a system as provided in the top-down schematic illustrated in FIG. 11 which combines wet chambers 1110 and a dry plasma chamber 1120 in a single platform. The wet chambers 1110 have in-situ drying capability such that reticles are handled “dry-in/dry-out” by the robot 1130. The dry plasma chamber 1120 can use an inductively coupled plasma (ICP) source to provide remote RF energy, as well as a gas distribution plate through which the gas stream with neutral radicals flows to reach a heated processing pedestal. The system of FIG. 11 allows for a reticle to be stripped, cleaned, rinsed, and dried without flipping all within the same platform.

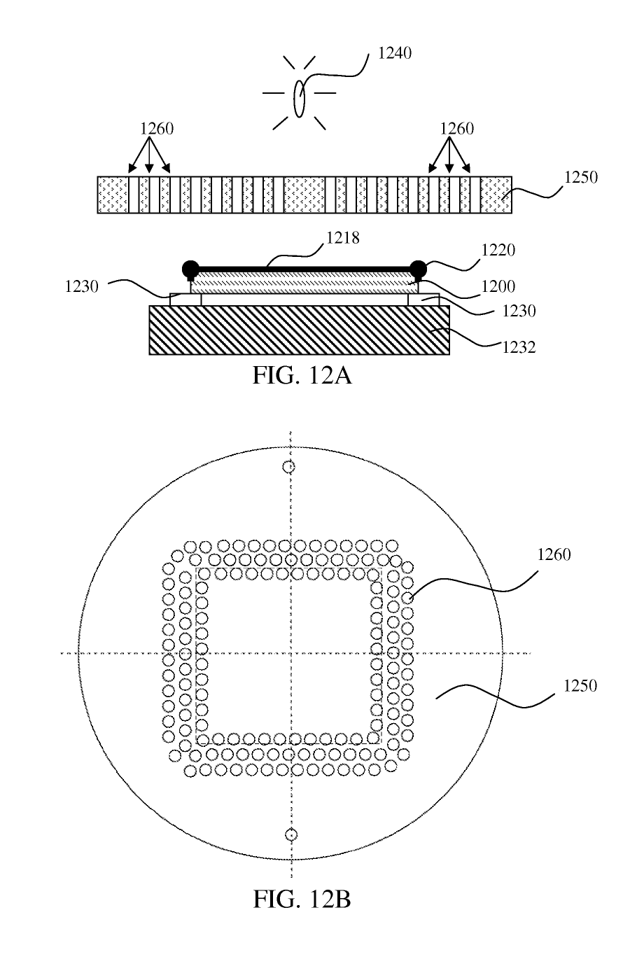

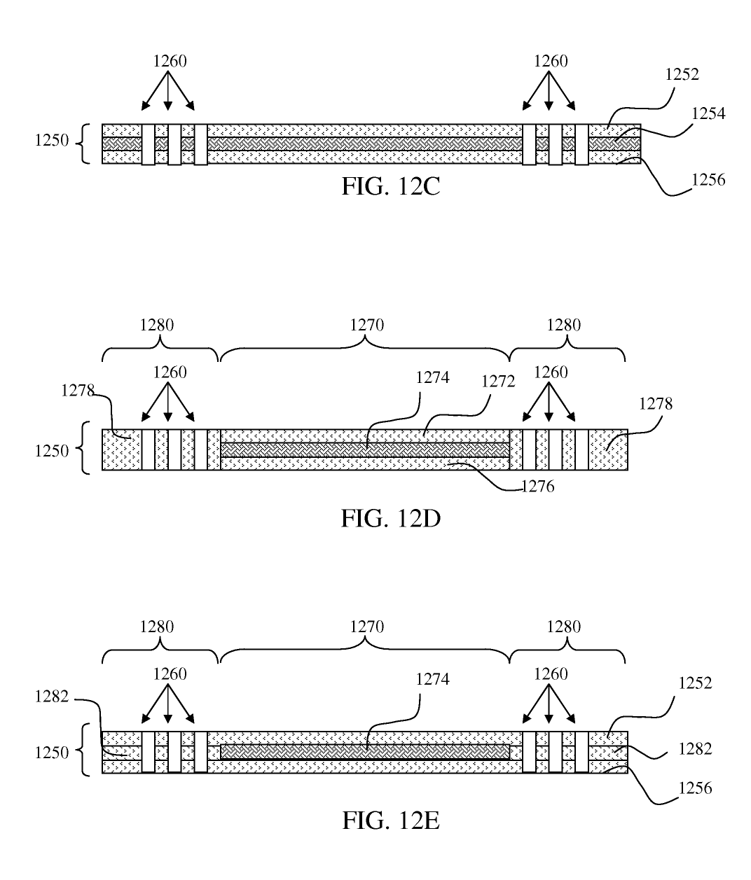

A more detailed illustration of an embodiment of the dry plasma chamber 1120 of FIG. 11 is provided in FIG. 12A. A reticle 1200 with a resist layer 1218 including resist bumps 1220 may be transferred to the dry plasma chamber by the robot 1130 of FIG. 11, and placed onto a reticle holder 1230. The reticle holder 1230 minimally contacts the reticle 1200 on its four corners and holds the reticle 1200 in a uniform spaced apart relation with a support pedestal 1232. The support pedestal 1232 may additionally include a heater (not shown). A plasma source 1240 is located above the reticle holder 1230 and reticle 1200. A gas distribution plate (GDP) 1250 having through hole pattern 1260 separates the reticle holder 1230 and reticle 1200 from the plasma source 1240.

In an embodiment, the GDP 1250 controls the heat load to the reticle 1200 to ensure the reticle maximum temperature and temperature uniformity do not cause warpage or flatness change of the reticle 1200. It is necessary that the flatness of the reticle 1200 be maintained to ensure good lithography or printing performance. The heat load consists of multiple contributors such as recombination of high energy radicals, convection of heated gas stream, and radiation from heated chamber components in proximity to the plasma source, especially the gas distribution plate. Control of the heat load is particularly challenging for reticles because unlike wafers, the reticle cannot come into contact with the support pedestal 1232. Thus, mechanical or electrostatic chucking with backside heat transfer gas such as helium as used with wafer processing is not feasible for reticles.

In an embodiment, the GDP perforation pattern can be a circular layout of holes at progressively larger “bolt circle” diameters from the center to the outside edge of the GDP plate (not shown) in order to provide improved uniform flow and flux of radicals to a substrate such as a reticle or wafer. Alternatively, as shown in FIG. 12B, in one embodiment the GDP 1250 includes a rectangular perforation pattern including multiple perforations 1260 which is positioned approximately vertically above the edges of a square reticle. In an embodiment the rectangular perforation pattern is a square pattern. The square perforation pattern may include a single square outline pattern or multiple square outline patterns. The square outline pattern is particularly useful for providing an intentional non-uniform flux of radicals to the outside edges of a square reticle to enhance removal of resist bumps on the edge of the reticle, while reducing the effective amount of overstrip or chemical contact on the rest of the reticle, which helps maintain the optical integrity of the reticle films.

In an embodiment, a three layer GDP assembly 1250 is utilized in order to reduce the heat loading to the reticle. The perforation pattern design of FIG. 12B can be implemented on a single layer and also a three layer GDP assembly 1250. An embodiment of a three layer GDP assembly is shown in FIG. 12C where the GDP assembly 1250 includes an intermediate plate 1254 which is opaque to infra-red (IR) radiation sandwiched between a top plate 1252 and a bottom plate 1256. The top and bottom plates 1252, 1256 are formed of a material which has a lower surface recombination rate for radical species than the intermediate plate 1254. In an embodiment, the intermediate plate is formed of silicon or aluminum (or any other suitable metal). In an embodiment, the top and bottom plates 1252, 1256 are formed of quartz. In an embodiment, all three plates 1252, 1254, 1256 have the same hole pattern 1260 to provide a flux of radicals to the reticle.

FIG. 12D is an illustration of another embodiment of a three layer GDP assembly. The GDP assembly 1250 includes an inner region 1270, which is designed to have a width or diameter equal to or greater than that of the reticle being processed, and an outer region 1280 which includes the hole pattern 1260. The inner region 1270 includes an intermediate plate 1274, top plate 1272 and bottom plate 1276. Intermediate plate 1274 is opaque to infra-red (IR) radiation. The top and bottom plates 1272, 1276 are formed of a material which has a lower surface recombination rate for radical species than the intermediate plate 1274. In an embodiment, the intermediate plate 1274 is formed of silicon or aluminum (or any other suitable metal). In an embodiment, the top and bottom plates 1272, 1276 are formed of quartz. The outer region 1280 includes a single plate 1278 which includes the hole pattern 1260. Plate 1278 is also formed of a material with a lower surface recombination rate for radical species such as quartz.

FIG. 12E is an illustration of another embodiment of a three layer GDP assembly. The GDP assembly 1250 includes an inner region 1270, which is designed to have a width or diameter equal to or greater than that of the reticle being processed, and an outer region 1280 which includes the hole pattern 1260. GDP assembly 1250 includes top and bottom plates 1252, 1256 which are identical to those described in relation to FIG. 12C. Sandwiched between the top and bottom plates 1252, 1256 are plates 1274 and 1282. Plate 1274 is identical to plate 1274 described in relation to FIG. 12D. Plate 1282 is not formed of a material that is opaque to infrared (IR) radiation, and may be formed of quartz. In the embodiment illustrated in FIG. 12E, all three plates 1252, 1256, 1282 have the same hole pattern 1260 to provide a flux of radicals to the reticle.

The three layer GDP assembly in accordance with embodiments of the present invention is found to result in lower average and maximum temperatures of the reticle, more uniform heat loading across the reticle, reduced flatness change, and in turn reduced image shift than with a conventional single layer quartz GDP plate.

In the foregoing specification, various embodiments of the invention have been described. It will, however, be evident that various modifications and changes may be made thereto without departing from the broader spirit and scope of the invention as set forth in the appended claims. The specification and drawings are, accordingly, to be regarded in an illustrative sense rather than a restrictive sense.

What is claimed is:

1. A method of processing a reticle comprising:
applying a H₂O vapor based plasma treatment to a reticle having a resist disposed on a top surface; and
applying a wet clean solution to the reticle.

2. The method of claim 1, further comprising supporting the reticle on a reticle holder and in spaced apart relation from a processing pedestal while applying the H₂O vapor based plasma treatment.

3. The method of claim 2, wherein the H₂O vapor based plasma treatment further comprises a gas selected from the group consisting of O₂, H₂, Ar, and He.

4. The method of claim 2, further comprising applying the H₂O vapor based plasma treatment for 15-60 seconds to substantially remove organic residues and convert the top surface of the reticle from a hydrophobic condition to hydrophilic condition.

5. The method of claim 4, wherein the reticle is selected from the group consisting of a new reticle, a reticle which has been stored for later lithography rework, and a reticle which has been stored after post-etch stripping.

6. The method of claim 2, further comprising applying the H₂O vapor based plasma treatment for 30-180 seconds; and wherein organic particles having several to tens percent of their surface area in contact with the reticle are removed.

7. The method of claim 2, further comprising applying the H₂O vapor based plasma treatment for 60-600 seconds to substantially remove the bulk of a resist layer from a portion of the top surface of the reticle.

8. The method of claim 7, further comprising continuing the H₂O vapor based plasma treatment for an additional 50-100% duration after the bulk of the resist layer is removed from the top portion of the reticle to remove the bulk of the resist layer near edges of the reticle.

9. The method of claim 2, further comprising:
applying a first wet clean solution comprising NH₄OH and H₂O₂ to the reticle prior to the plasma treatment.

10. The method of claim 9, further comprising:
performing a plasma etching operation on the reticle prior to applying the H₂O vapor based plasma treatment, wherein organic residuals form on the reticle during the plasma etching operation; and
removing the organic residuals during the H₂O vapor based plasma treatment.

11. The method of claim 9, further comprising applying the H₂O vapor based plasma treatment for 60-600 seconds.

12. The method of claim 11, further comprising applying a first H₂O vapor based plasma treatment for 15-60 seconds to convert the top surface of the reticle from a hydrophobic condition to hydrophilic condition prior to applying the H₂O vapor based plasma treatment.

13. The method of claim 2, wherein the wet clean solution is applied in a wet clean chamber, and the H₂O vapor based plasma treatment is performed in a plasma chamber comprising the reticle holder, the processing pedestal, and a gas distribution plate including:
a top plate;
a intermediate plate which is opaque to infra-red (IR) radiation; and
a bottom plate;
wherein the top and bottom plates are formed of a material which has a lower surface recombination rate for radical species than the intermediate plate.

14. A method of stripping resist comprising:
transferring a reticle to a dry processing chamber comprising a reticle holder and a processing pedestal;
placing the reticle onto the reticle holder and in spaced apart relation with the processing pedestal, the reticle having a resist layer disposed on a top surface of the reticle;
applying a H₂O vapor based plasma treatment to the reticle, wherein the H₂O vapor based plasma treatment further includes a gas;
transferring the reticle to a wet processing chamber; and
applying a wet clean solution to the reticle.

15. The method of claim 14, wherein the gas is selected from the group consisting of O₂, H₂, Ar, and He.

16. The method of claim 14, wherein the dry processing chamber further comprises a gas distribution plate including:
a top plate;
a intermediate plate which is opaque to infra-red (IR) radiation; and
a bottom plate;
wherein the top and bottom plates are formed of a material which has a lower surface recombination rate for radical species than the intermediate plate.

17. The method of claim 14, wherein applying the plasma treatment removes the bulk of the resist layer from the top surface of the reticle.

18. The method of claim 14, wherein applying the plasma treatment converts the top surface of the reticle from a hydrophobic condition to hydrophilic condition.

19. A gas distribution plate comprising:
a top plate;
a intermediate plate which is opaque to infra-red (IR) radiation; and
a bottom plate;
wherein the top and bottom plates are formed of a material which has a lower surface recombination rate for radical species than the intermediate plate.

20. The gas distribution plate of claim 19, wherein the intermediate plate is comprised of crystalline silicon or a metal.

21. The gas distribution plate of claim 19, wherein the top and bottom plates are comprised of quartz.

22. The gas distribution plate of claim 19, wherein the top, intermediate, and top plates have an aligned square perforation pattern.

23. The gas distribution plate of claim 22, wherein the square perforation pattern includes multiple individual perforations arranged in multiple square outline patterns.
